(19) United States
(12) Patent Application Publication
(10) Pub. No.: US 2005/0127487 A1
(43) Pub. Date: Jun. 16, 2005

(54) Semiconductor package with improved solder joint reliability

(76) Inventor: Tae-Sub Chang, Seoul (KR)

Correspondence Address: MARGER JOHNSON & MCCOLLOM, P.C., 1030 SW MORRISON STREET, PORTLAND, OR, 97205, US

(21) Appl. No.: 11/008,906

(22) Filed: Dec. 10, 2004

(30) Foreign Application Priority Data
Dec. 12, 2003 (KR) 2003-90681

(51) Int. Cl. H01L 23/48

(52) U.S. Cl. 257/678

(57) ABSTRACT

A semiconductor package has an improved solder joint reliability. The package includes a semiconductor chip having chip pads, and metal lines electrically coupled to the chip pads. The package further includes ball lands provided on a ball-forming surface and electrically coupled to the metal lines. A solder resist covers the ball-forming surface, and solder balls are formed on the respective ball lands. Each ball land has a first part facing a center of the ball-forming surface and a second part opposing the first part. The first part is covered with the solder resist and the second part is exposed to an opening defined by the solder resist.

### CROSS REFERENCE TO RELATED APPLICATIONS

This U.S. non-provisional application claims priority under 35 U.S.C. § 119 to Korean Patent Application No. 2003-90681 filed Dec. 12, 2003, the content of which is incorporated by reference in its entirety for all purposes.

### BACKGROUND OF THE INVENTION

1. Field of the Invention

This disclosure invention relates generally to electronic packaging technology and, more particularly, to a semiconductor package having an improved solder joint reliability.

2. Description of the Related Art

FIG. 1 shows, in a cross-sectional view, a conventional semiconductor package 2. Referring to FIG. 1, the package 2 includes a semiconductor chip 10, an insulating layer 21, metal lines 22, solder ball lands 23, a solder resist 24, and solder balls 31.

The semiconductor chip 10 has a plurality of chip pads 12 formed thereon, and a passivation layer 13 covering the chip 10 except for the chip pads 12. The insulating layer 21 covers the passivation layer 13, and the metal lines 22 are provided on the insulating layer 21. Each metal line 22 is electrically coupled to the chip pad 12 at one end. The solder ball land 23 is provided at the other end of each metal line 22 on the insulating layer 21. The solder resist 24 coats the insulating layer 21 and the metal lines 22 and exposes the solder ball lands 23. The solder balls 31 are formed on the respective solder ball lands 23 and joined to a next-level board 1 such as a motherboard. The package 2 is mechanically and electrically connected to the board 1 through the solder balls 31.

FIG. 2 illustrates, in a plan view, the solder ball land 23 of the package 2 shown in FIG. 1. Referring to FIG. 2, most parts of the solder ball land 23 are exposed through the solder resist 24, but a peripheral part 23a of the solder ball land 23 is covered with the solder resist 24. That is, such a structure of the solder ball land 23 is similar to a solder mask defined (SMD) type as well known in this art.

The above-described conventional package 2 may have shortcomings, as follows. While the chip 10, for example, made of silicon, has the coefficient of thermal expansion (CTE) of about 3.6 ppm/° C., the next-level board 1 has typically the CTE of about 18 ppm/° C. Namely, there is a significant difference in the CTE between the chip 10 and the board 1. Therefore, when a heat for solder reflow is removed, the board 1 shrinks at a higher rate than the chip 10. This different contraction stresses the solder balls 31, as indicated by T1 and T2 in FIG. 1. Accordingly, the solder balls 31 may be often detached from the solder ball lands 23 at outer edges, as indicated by S1 and S2 in FIG. 1.

To solve the above problem of solder joint, the solder ball land may have another structure well known as a non-solder mask defined (NSMD) type, that is, the entire parts of the solder ball land are exposed outside the solder resist. The NSMD type structure may, however, cause another solder joint problem. Since the solder resist fails to support the solder ball lands in case of the NSMD type, the solder ball lands themselves may be peeled from a surface of the package in vibration surroundings. Embodiments of the invention address these and other disclosures of the conventional art.

### SUMMARY OF THE INVENTION

Exemplary embodiments of the present invention may provide a semiconductor package having an improved solder joint reliability.

### BRIEF DESCRIPTION OF THE DRAWINGS

FIG. 1 is a cross-sectional view of a conventional semiconductor package.

FIG. 2 is a plan view illustrating solder ball lands of the package shown in FIG. 1.

FIG. 3 is a cross-sectional view of a semiconductor package in accordance with some embodiments of the invention.

FIG. 4 is a plan view illustrating solder ball lands of the package shown in FIG. 3.

FIG. 5 is a view illustrating a first straight line shown in FIG. 4.

FIG. 6 is an enlarged view of a section “D1” in FIG. 3.

FIG. 7 is a plan view partially illustrating a ball-forming surface of the package shown in FIG. 3.

FIG. 8 is a cross-sectional view of a semiconductor package in accordance with other embodiments of the invention.

FIG. 9 is a plan view illustrating bump lands of a substrate shown in FIG. 8.

FIG. 10 is a cross-sectional view of a semiconductor package in accordance with still other embodiments of the invention.

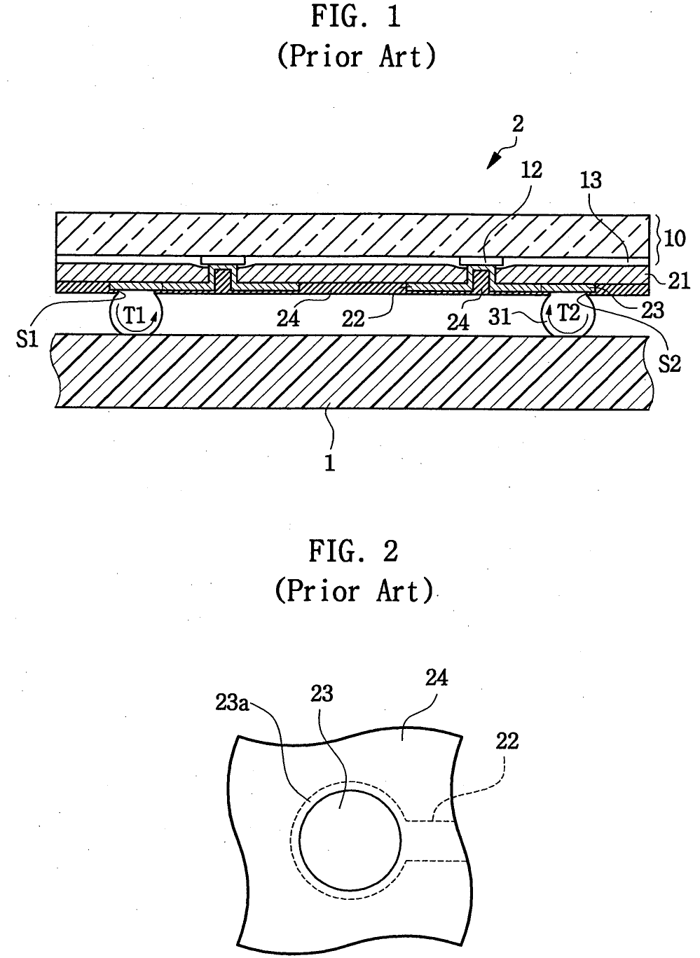

### DETAILED DESCRIPTION OF THE INVENTION

Exemplary, non-limiting embodiments of the invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

In the description, well-known structures and processes have not been described or illustrated in detail to avoid obscuring the present invention. It will be appreciated that the figures are not drawn to scale. Rather, for simplicity and clarity of illustration, the dimensions of some of the elements are exaggerated relative to other elements. Like numerals and characters are used for like and corresponding parts of the various drawings.

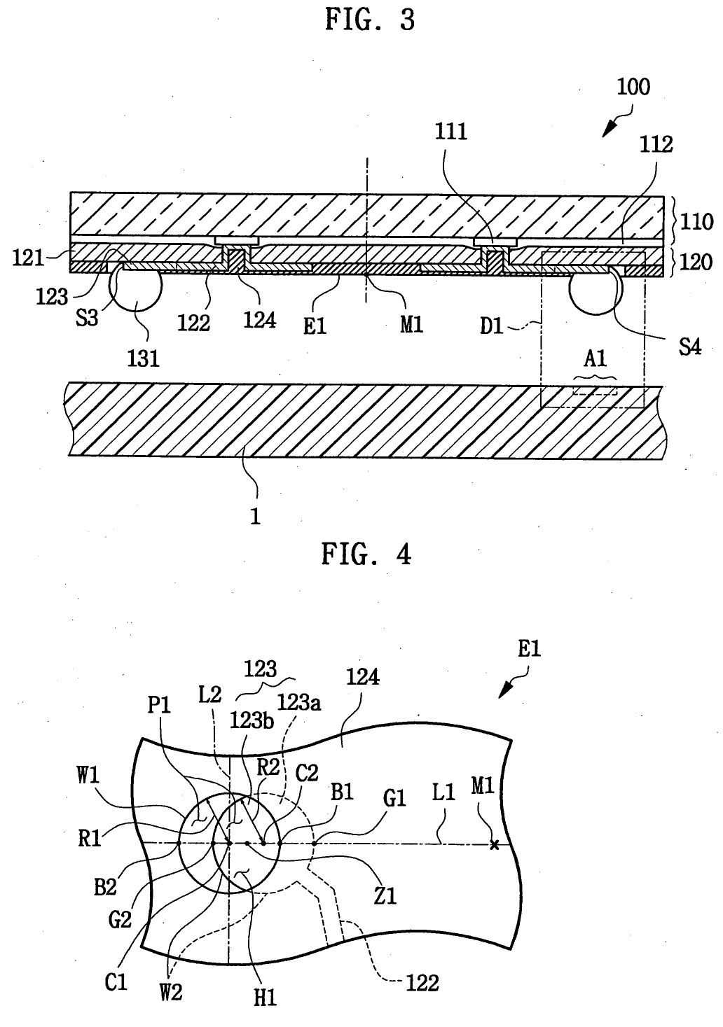

FIG. 3 illustrates, in a cross-sectional view, a semiconductor package 100 in accordance with some exemplary embodiments of the invention. As shown in FIG. 3, the package 100 includes a semiconductor chip 110, a rerouting region 120, and solder balls 131. The package 100 may be fabricated at a wafer level like a wafer level package.

The chip 110 has a plurality of chip pads 111 disposed on an active surface of the chip 110. The chip 110 further has a passivation layer 112 covering the active surface, except for the chip pads 111.

The rerouting region 120 has an insulating layer 121, metal lines 122, solder ball lands 123, and a solder resist 124. The insulating layer 121 covers the passivation layer 112 and exposes the chip pads 111. The metal lines 122 are provide on both the insulating layer 121 and the chip pads 111, so each metal line 122 is electrically coupled to the chip pad 12 at one end. Each solder ball land 123 is provided at the other end of each metal line 122 on the insulating layer 121. The solder resist 124 coats the insulating layer 121 and the metal lines 122 and partially exposes each solder ball land 123.

The solder balls 131 are formed on the respective solder ball lands 123. Each solder ball 131 is joined to a ball-mounting area A1 of a next-level board 1 such as a motherboard. The package 100 is mechanically and electrically connected to the board 1 through the solder balls 131.

In FIG. 3, a reference character E1 indicates a ball-forming surface, namely, on which the solder balls 131 are formed. Further, a reference character M1 indicates a center of the ball-forming surface E1. As discussed above, a reference character A1 indicates a ball-mounting area on which the solder ball 131 is mounted.

FIG. 4 shows, in a plan view, the solder ball land 123 provided on the ball-forming surface E1. As shown in FIG. 4, one part of the solder ball land 123 is exposed through the solder resist 124, and the other part of the solder ball land 123 is covered with the solder resist 124. That is, a center-oriented part 123a of the solder ball land 123 is covered with the solder resist 124, and the other part 123b is exposed to an opening P1 defined by the solder resist 124.

Specifically, a first straight line L1 is defined as a phantom line that starts from the center M1 of the ball-forming surface E1 and extends toward a center C1 of the opening P1. The first straight line L1 intersects an opening edge W1 of the opening P1 at inner and outer points B1 and B2. Also, the first straight line L1 intersects a land edge W2 of the solder ball land 123 at inner and outer points G1 and G2. A distance between the inner point B1 of the opening edge W1 and the center M1 of the ball-forming surface E1 is longer than a distance between the inner point G1 of the land edge W2 and the center M1 of the ball-forming surface E1. Similarly, a distance between the outer point B2 of the opening edge W1 and the center M1 of the ball-forming surface E1 is longer than a distance between the outer point G2 of the land edge W2 and the center Ml of the ball-forming surface E1.

The opening edge W1 may form a circle having the center C1 and a radius R1. Similarly, the land edge W2 may form a circle having the center C2 and a radius R2.

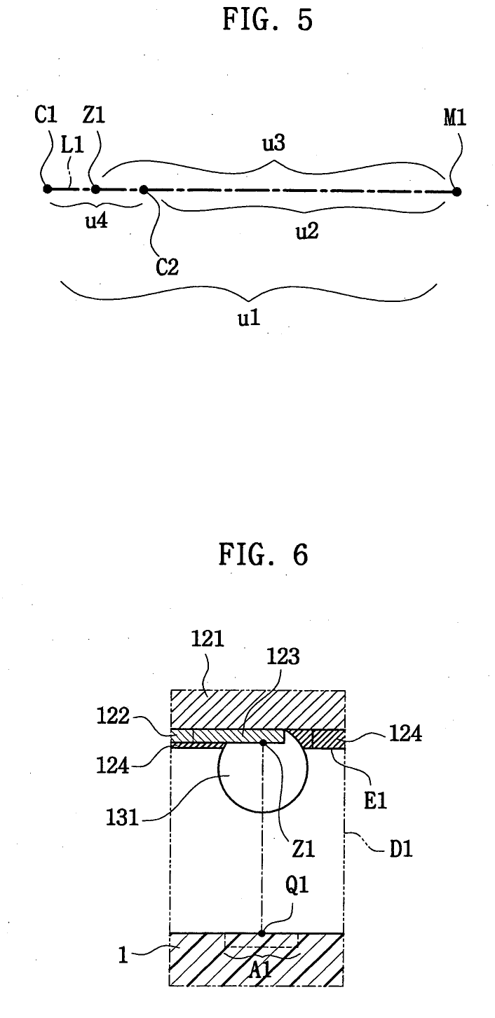

The first straight line L1 is further illustrated in FIG. 5. Referring to FIG. 5, a first segment u1 connecting the centers M1 and C1 has a length longer than that of a second segment u2 connecting the centers M1 and C2.

FIG. 6 is an enlarged view of a section “D1” in FIG. 3. As shown in FIG. 6, when the solder ball 131 is mounted on the ball-mounting area Al of the board 1, a projected point Z1 on the solder ball land 123 corresponds to a center Q1 of the ball-mounting area A1. Returning to FIG. 5, a length of a third segment u3 connecting the projected point Z1 and the center M1 is shorter than that of the first segment u1 and longer than that of the second segment u2. In addition, the projected point Z1 may be located on a fourth segment u4 connecting the centers C1 and C2.

Returning to FIG. 4, the radius R1 of the opening edge W1 may be 0.9 to 1.3 times as long as the radius R2 of the land edge W2. Further, when an inner semicircle Hi is defined by a second straight line L2 perpendicular to the first straight line L1 at the center C1 of the opening edge W1, the center C2 of the land edge W2 may be located within the inner semicircle H1 of the opening P1. A length of the fourth segment u4 between the both centers C1 and C2 may be about 20˜70 μm.

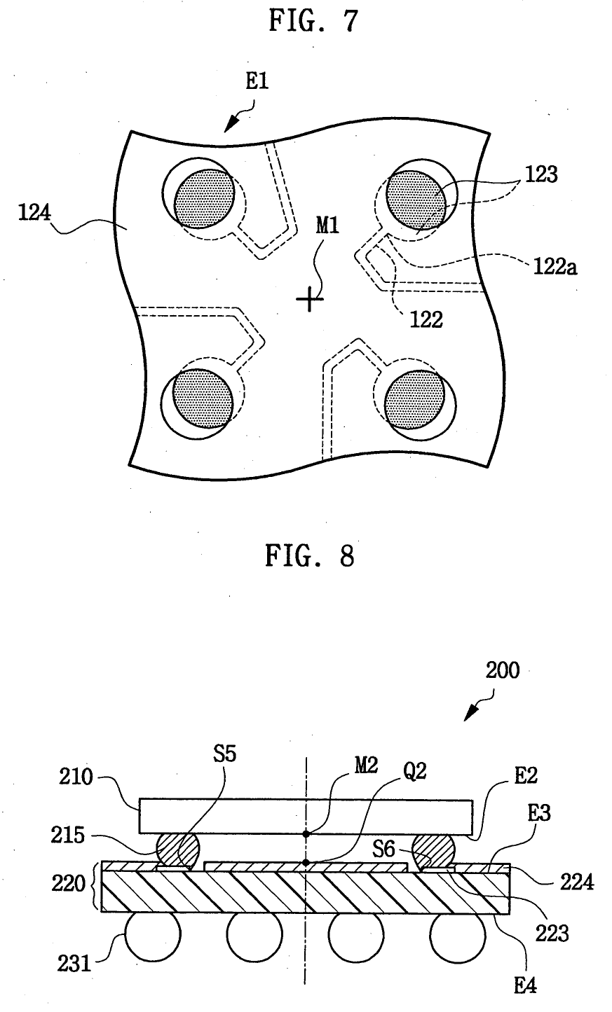

FIG. 7 illustrates, in a plan view, parts of the ball-forming surface E1 of the package shown in FIG. 3. As shown in FIG. 7, each metal line 122 is connected to the solder ball land 123 at a connection point 122a. In particular, each connection point 122a faces the center M1 of the ball-forming surface E1, and the metal line 122 extends toward the center M1 from the connection point 122a.

As illustrated in FIG. 3, the package 100 according to this embodiment has an improved configuration of the solder ball land 123 including an NSMD type outer edge, as indicated by S3 and S4. This provides enhanced attachment between the solder ball 131 and the solder ball land 123, so prevents the solder ball 131 from being detached from the solder ball land 123 at outer edges S3 and S4. Further, an inner edge of the solder ball land 123 is a SMD type. This prevents the solder ball lands 123 from being peeled from the insulating layer 121. Accordingly, the package 100 according to this embodiment has an improved solder joint reliability.

FIG. 8 illustrates, in a cross-sectional view, a semiconductor package 200 in accordance with other embodiments of the invention. As shown in FIG. 8, the package 200 includes a semiconductor chip 210, solder bumps 215, a substrate 220, and solder balls 231. The chip 210 is attached to the substrate 220 in a flip-chip fashion.

The chip 210 has a bump-forming surface E2 on which the solder bumps 215 are formed. The substrate 220 has bump lands 223 on which the solder bumps 215 are mounted. The bump lands 223 are formed on a bump-mounting surface E3 of the substrate 220. The bump-mounting surface E3 is covered with a solder resist 224, except for the bump lands 223. The solder balls 231 are formed on a back surface E4 opposing the bump-mounting surface E3.

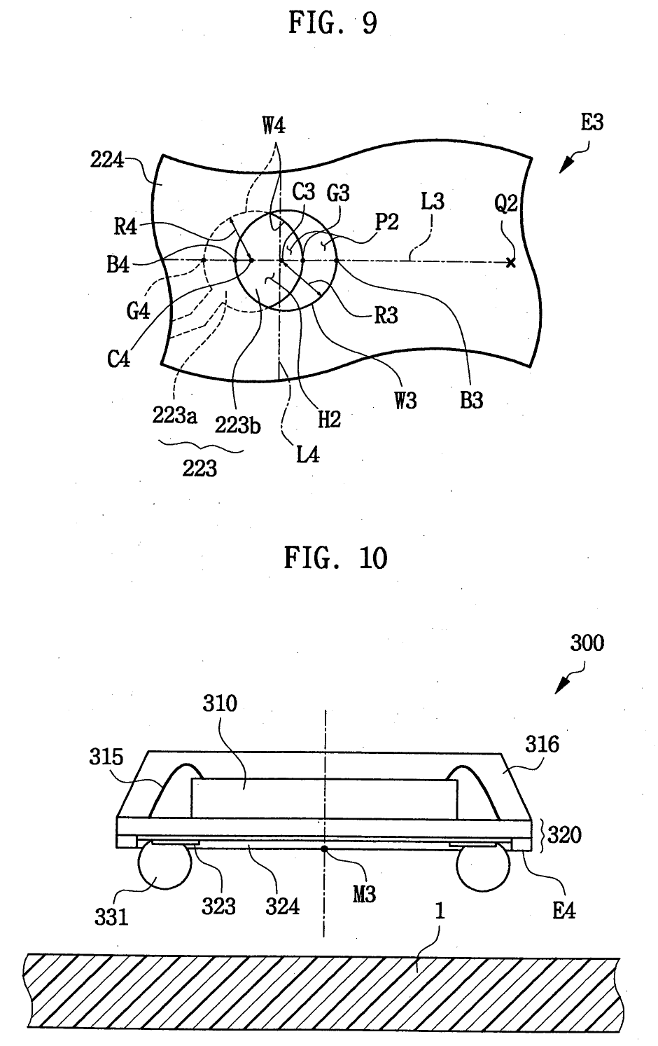

FIG. 9 illustrates, in a plan view, the bump lands 223 provided on the bump-mounting surface E3 of the substrate 220. Referring to FIGS. 8 and 9, an outside-oriented part 223a of the bump land 223 is covered with the solder resist 224, and the other part 223b is exposed to an opening P2 defined by the solder resist 224.

Specifically, a third straight line L3 is defined as a phantom line that starts from a projected point Q2 of the bump-mounting surface E3, which corresponds to a center M2 of the bump-forming surface E2, and extends toward a center of the opening P2. The third straight line L3 intersects an opening edge W3 of the opening P2 at inner and outer points B3 and B4. Also, the third straight line L3 intersects a land edge W4 of the bump land 223 at inner and outer points G3 and G4. A distance between the inner point B3 of the opening edge W3 and the projected point Q2 of the bump-mounting surface E3 is shorter than a distance between the inner point G3 of the land edge W4 and the projected point Q2 of the bump-mounting surface E3. Similarly, a distance between the outer point B4 of the opening edge W3 and the projected point Q2 of the bump-mounting surface E3 is shorter than a distance between the outer point G4 of the land edge W4 and the projected point Q2 of the bump-mounting surface E3.

The opening edge W3 may form a circle having the center C3 and a radius R3. Similarly, the land edge W4 may form a circle having the center C4 and a radius R4. Further, a distance between the projected point Q2 and the center C3 is shorter than a distance between the projected point Q2 and the center C4.

The radius R3 of the opening edge W3 may be 0.9 to 1.3 times as long as the radius R4 of the land edge W4. Further, when an outer semicircle H2 is defined by a fourth straight line L4 perpendicular to the third straight line L3 at the center C3 of the opening edge W3, the center C4 of the land edge W4 may be located within the outer semicircle H2 of the opening P2. A length between the both centers C3 and C4 may be about 10˜60 μm.

As illustrated in FIG. 8, the package 200 according to this embodiment has an improved configuration of the bump land 223 including an NSMD type outer edge, as indicated by S5 and S6. This provides enhanced attachment between the solder bump 215 and the bump land 223, so prevents the solder bump 215 from being detached from the bump land 223 at outer edges S5 and S6. Further, an inner edge of the bump land 223 is a SMD type. This prevents the bump lands 223 from being peeled from the substrate 220. Accordingly, the package 200 according to this embodiment has an improved solder joint reliability, and may be provided without underfill material (as in conventional flip-chip packages).

FIG. 10 illustrates, in a cross-sectional view, a semiconductor package 300 in accordance with still other embodiments of the invention. As shown in FIG. 10, the package 300 includes a semiconductor chip 310, a substrate 320, bonding wires 315, an encapsulating body 316, and solder balls 331. The package 300 may be a kind of a ball grid array (BGA) package.

The chip 310 is attached on the substrate 320 and electrically coupled thereto through the bonding wires 315. The encapsulating body 316 covers the chip 310, the bonding wires 315, and a chip-attaching surface of the substrate 320. For electrical connections to a next-level board 1, the solder balls 331 are formed on the respective ball lands 323 provided on a ball-forming surface E4 of the substrate 320. A part of the ball land 323 is exposed through a solder resist 324, and the other part is covered with the solder resist 324. A reference character M3 indicates a center of the ball-forming surface E4.

The ball land 323 of these embodiments are similar in configuration to the ball land of the embodiments.

As stated above, those skilled in this art will appreciate that the above-discussed configuration of the ball land may be applied to the package in this embodiment. Therefore, a detailed description of the same is not provided.

In this embodiment, the CTE of the entire package 300 approaches the CTE of the bare chip 310. Therefore, the package 300 may have a thermal stress due to a difference in the CTE between the package 300 and the next-level board 1. However, the configuration of the ball lands 323 improves solder joint reliability of the solder balls 331.

According to some embodiments of the invention, a semiconductor package includes a semiconductor chip that has a plurality of chip pads. The package further includes metal lines electrically coupled to the chip pads, ball lands provided on a ball-forming surface and electrically coupled to the metal lines, a solder resist covering the ball-forming surface and defining an opening, and solder balls formed on the respective ball lands. Each ball land has a first part facing a center of the ball-forming surface and a second part opposing the first part. The first part is covered with the solder resist and the second part is exposed to the opening.

The invention may be practiced in many ways. What follows are exemplary, non-limiting descriptions of some embodiments of the invention.

While this invention has been particularly shown and described with reference to exemplary embodiments thereof, it will be understood by those skilled in the art that various changes in form and details may be made therein without departing from the spirit and scope of the invention as defined by the appended claims.

According to other embodiments of the invention, a semiconductor package includes a semiconductor chip that has a bump-forming surface on which solder bumps are formed. The package further includes a substrate that has a bump-mounting surface on which bump lands are formed. The solder bumps are mounted on the bump lands, and the bump-mounting surface is covered with a solder resist. The package further includes solder balls formed on a back surface opposing the bump-mounting surface of the substrate. Each bump land has a first part facing an outside of the bump-mounting surface and a second part opposing the first part. The first part is covered with the solder resist and the second part is exposed to an opening defined by the solder resist.

According to other embodiments of the invention, a semiconductor package includes a semiconductor chip, and a substrate that has a chip-attaching surface on which the chip is attached, and a ball-forming surface on which ball lands are formed. The ball-forming surface is covered with a solder resist. The package further includes solder bumps formed on the ball lands. Each ball land has a first part facing a center of the ball-forming surface and a second part opposing the first part. The first part is covered with the solder resist and the second part is exposed to an opening defined by the solder resist.

1. A semiconductor package comprising:
a semiconductor chip including chip pads;
metal lines electrically coupled to the chip pads;
ball lands provided on a ball-forming surface and electrically coupled to the metal lines;
a solder resist covering the ball-forming surface and defining an opening; and
solder balls formed on the respective ball lands,
wherein each ball land has a first part facing a center of the ball-forming surface and a second part opposing the first part, and wherein the first part is covered with the solder resist and the second part is exposed to the opening.

2. The package of claim 1, arranged such that a straight line starting from the center of the ball-forming surface and extending toward a center of the opening intersects an opening edge of the opening at inner and outer points, and also intersects a land edge of the ball land at inner and outer points, a distance between the inner point of the opening edge and the center of the ball-forming surface longer than a distance between the inner point of the land edge and the center of the ball-forming surface.

3. The package of claim 1, arranged such that a straight line starting from the center of the ball-forming surface and extending toward a center of the opening intersects an opening edge of the opening at inner and outer points, and also intersects a land edge of the ball land at inner and outer points, a distance between the outer point of the opening edge and the center of the ball-forming surface longer than a distance between the outer point of the land edge and the center of the ball-forming surface.

4. The package of claim 1, wherein the opening includes an opening edge forming a circle having a first center and a first radius, and wherein the ball land includes a land edge forming a circle having a second center and a second radius.

5. The package of claim 4, wherein a first segment connecting the center of the ball-forming surface and the first center has a length longer than that of a second segment connecting the center of the ball-forming surface and the second center.

6. The package of claim 5, wherein, when the solder ball is mounted on a ball-mounting area of a next-level board, a projected point on the ball land corresponds to a center of the ball-mounting area, wherein a length of a third segment connecting the projected point and the center of the ball-forming surface is shorter than that of the first segment and longer than that of the second segment.

7. The package of claim 6, wherein the projected point is located on a fourth segment connecting the first and second centers.

8. The package of claim 4, wherein the first radius is 0.9 to 1.3 times as long as the second radius.

9. The package of claim 4, arranged such that an inner semicircle is defined by a first straight line starting from the center of the ball-forming surface and extending toward a center of the opening and a second straight line perpendicular to the first straight line at the first center of the opening edge, and wherein the second center of the land edge is located within the inner semicircle of the opening.

10. The package of claim 7, wherein a length of the fourth segment is about 20˜70 mm.

11. A semiconductor package comprising:
a semiconductor chip including a bump-forming surface on which solder bumps are formed;
a substrate including a bump-mounting surface on which bump lands are formed, the solder bumps mounted on the bump lands, and the bump-mounting surface covered with a solder resist; and
solder balls formed on a back surface of the substrate, the back surface opposite the bump-routing surface,
wherein each bump land has a first part facing an outside of the bump-mounting surface and a second part opposing the first part, and wherein the first part is covered with the solder resist and the second part is exposed to an opening defined by the solder resist.

12. The package of claim 11, structured such that a straight line starting from a projected point of the bump-mounting surface, the projected point corresponding to a center of the bump-forming surface, and extending toward a center of the opening intersects an opening edge of the opening at inner and outer points, and also intersects a land edge of the bump land at inner and outer points, a distance between the inner point of the opening edge and the projected point of the bump-mounting surface less than a distance between the inner point of the land edge and the projected point of the bump-mounting surface.

13. The package of claim 11, structured such that a straight line starting from a projected point of the bump-mounting surface, the projected point corresponding to a center of the bump-forming surface, and extending toward a center of the opening intersects an opening edge of the opening at inner and outer points, and also intersects a land edge of the bump land at inner and outer points, a distance between the outer point of the opening edge and the projected point of the bump-mounting surface less than a distance between the outer point of the land edge and the projected point of the bump-mounting surface.

14. The package of claim 11, wherein the opening includes an opening edge forming a circle having a first center and a first radius, and wherein the bump land includes a land edge forming a circle having a second center and a second radius.

15. The package of claim 14, wherein a first segment connecting the projected point of the bump-mounting surface and the first center has a length less than that of a second segment connecting the projected point of the bump-mounting surface and the second center.

16. The package of claim 14, wherein the first radius is 0.9 to 1.3 times as long as the second radius.

17. The package of claim 14, structured such that an outer semicircle is defined by a first straight line starting from a projected point of the bump-mounting surface, the projected point corresponding to a center of the bump-forming surface, and extending toward a center of the opening, and a second straight line perpendicular to the first straight line at the third center of the opening edge, the second center located within the outer semicircle.

18. The package of claim 17, wherein the first and second centers are about 10˜60 μm apart.

19. A semiconductor package comprising:
a semiconductor chip;
a substrate including a chip-attaching surface on which the chip is attached, and a ball-forming surface on which ball lands are formed, the ball-forming surface being covered with a solder resist; and
solder bumps formed on the ball lands, each ball land having a first part facing a center of the ball-forming surface and a second part opposing the first part, the first part covered with the solder resist and the second part exposed to an opening defined by the solder resist.

20. The package of claim 19, structured such that a straight line starting from the center of the ball-forming surface and extending toward a center of the opening intersects an opening edge of the opening at inner and outer points, and also intersects a land edge of the ball land at inner and outer points, wherein a distance between the inner point of the opening edge and the center of the ball-forming surface greater than a distance between the inner point of the land edge and the center of the ball-forming surface.

21. The package of claim 19, structured such that a straight line starting from the center of the ball-forming surface and extending toward a center of the opening intersects an opening edge of the opening at inner and outer points, and also intersects a land edge of the ball land at inner and outer points, a distance between the outer point of the opening edge and the center of the ball-forming surface greater than a distance between the outer point of the land edge and the center of the ball-forming surface.

22. The package of claim 19, wherein the opening includes an opening edge forming a circle having a first center and a first radius, and wherein the ball land includes a land edge forming a circle having a second center and a second radius.

23. The package of claim 22, wherein a first segment connecting the center of the ball-forming surface and the first center is greater than a second segment connecting the center of the ball-forming surface and the second center.

24. The package of claim 23, further comprising a solder ball mounted on a ball-mounting area of a next-level board, a projected point on the ball land corresponding to a center of the ball-mounting area, a length of a third segment connecting the projected point and the center of the ball-forming surface is less than that of the first segment and greater than that of the second segment.

25. The package of claim 24, wherein the projected point is located on a fourth segment connecting the first and second centers.

26. The package of claim 22, wherein the first radius is 0.9 to 1.3 times as long as the second radius.

27. The package of claim 22, is an inner semicircle defined by a first straight line that starts from the center of the ball-forming surface and extends toward a center of the opening, a second straight line perpendicular to the first straight line at the first center of the opening edge, the second center of the land edge located within the inner semicircle of the opening.

28. The package of claim 25, wherein a length of the fourth segment is about 20˜70 μm.
